(19) United States
(12) Patent Application Publication
(10) Pub. No.: US 2026/0068078 A1
(43) Pub. Date: Mar. 5, 2026

(54) ADAPTABLE FAN GUARD

(71) Applicant: HEWLETT PACKARD ENTERPRISE DEVELOPMENT LP, Spring, TX (US)

(72) Inventors: Peng Chianghsieh, Taoyuan City (TW); Chih-Wei Chiang, Taoyuan City (TW); Yu Han Lin, Taoyuan City (TW)

(21) Appl. No.: 18/816,032

(22) Filed: Aug. 27, 2024

(51) Int. Cl. H05K 7/20; H05K 7/14

(52) U.S. Cl. CPC H05K 7/20172; H05K 7/1488

(57) ABSTRACT

An information processing system includes a printed circuit board assembly supported by a chassis and comprising a plurality of fan connectors. A fan support may be further coupled with the chassis. A fan module may be attached to the fan support. The fan module may comprise a fan rotor, an electrical connector to couple with a fan connector, and a fan housing containing the fan rotor. A pair of fan guards, each including a bracket, may be coupled to the fan housing. A connector holder may hold the electrical connector and may be interchangeably and removably able to be coupled to each one of the pair of fan guards.

Information processing systems, (e.g., computers) generate heat during operation and, if the heat is not dissipated or cooling is not provided, damage can occur to various components within the system. One way of cooling is installing fans, where the fans are electrically connected at fan connection points on the motherboard. Once installed, the fans are able to provide the necessary cooling for the system.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of an example information processing system including adaptable fan guards.

FIG. 2 is a perspective view of a fan module including an adaptable fan guard and an electrical connector coupled thereto.

FIG. 3 is a perspective view of the fan module of FIG. 2 including an adaptable fan guard with the electrical connector omitted.

FIG. 4 is a side view of the fan module of FIG. 3 including an adaptable fan guard.

FIG. 5 is a perspective view of the fan module of FIG. 2 including an adaptable fan guard with the connector holder removed.

FIG. 6 is an exploded perspective view of the fan module of FIG. 2 including an adaptable fan guard.

FIG. 7 is a top view of an adaptable fan guard and a connector holder of the fan module of FIG. 2 in a detached state.

FIG. 8 is a perspective view of the adaptable fan guard and connector holder of FIG. 7 in an attached state.

FIG. 9 is another perspective view of the adaptable fan guard and connector holder of FIG. 7 in the attached state.

FIG. 10 is another view of the adaptable fan guard and connector holder of FIG. 7 in the attached state.

FIG. 11 is a perspective view of an example system including fan modules having adaptable fan guards.

FIG. 12 is a process flow chart illustrating an example method for installing fans with an adaptable fan guard.

### DETAILED DESCRIPTION

Generally, fans are installed in an information processing system by attachment to a fan support that is coupled to the chassis of the system and by engagement of an electrical connector of the fan with an electrical connector on the primary system board of the system. In enterprise grade information processing systems (e.g., servers), the fans are often provided with fan guards which can, among other things, protect the fans and help facilitate the easier installation of the fans in the system. A fan usually has two fan guards which are attached to opposite sides of a housing of the fan, with each fan guard including portions which extend over an opening of the airflow channel through the fan to help prevent inadvertent insertion of objects into the opening (which may cause damage to the fan's blades). In addition, the fan guards may include mounting features to facilitate the attachment of the fan to a fan bracket.

Often, one of the fan guards attached to a fan also includes a connector holder, which is integrally formed with (i.e., part of the same monolithic body as) the fan guard. The connector holder holds the electrical connector of the fan in a predetermined position and orientation to allow it to mate with the electrical connector of the system board. The connector holder also includes handle features which a user can press against when engaging the fan's electrical connector with the system's electrical connector or pull upon when disengaging the fan's electrical connector.

However, one challenge with such fan guards is that they may limit the locations and the orientations at which their fans may be installed in a system. Generally, a primary system board may have electrical connectors which are to mate with the electrical connectors of the fans. Moreover, the electrical connectors of the fans are held in a fixed position relative to the fan by the connector holder thereof, and therefore the possible positions and orientations in which the fan can be installed are generally limited to only those positions and orientations of the fan which allow its connector holder to be aligned with a corresponding electrical connector of the primary system board. Accordingly, systems having different requirements for fan installation positioned/orientations may require different fan guard designs.

For instance, different information processing systems may orient their airflow in different directions. For example, some systems may direct airflow from front to rear, while other systems may direct airflow from rear to front. Most fans used in information processing systems can flow air in just one direction; therefore, to change the direction of airflow through the overall system, the orientations of the fans may need to be reversed. Said differently, a fan being installed in a system with front to rear airflow will need to be installed in an orientation in which its intake opening faces the front of the system and its exhaust opening faces the rear of the system, whereas a fan being installed in a system with a rear to front airflow would be installed in an opposite orientation. As the fan changes orientation, the connector holder thereof will move, and therefore it may not be possible for the connector holder to be aligned with one of the system board's electrical connectors while in both orientations. For example, if the connector holder is formed in the exhaust-side fan guard of the fan, when the fan is installed in a front-to-rear system the exhaust-side fan guard will be adjacent to the system board and thus the connector holder may be correctly positioned in alignment with an electrical connector of the system board. However, if the orientation of the same fan is reversed to provide rear-to-front airflow, then the exhaust-side fan guard will now be more distant from the system board and thus the connector holder thereof will no longer be aligned with the system board's electrical connector. Consequently, different fan guard designs may be needed for systems with different airflow directions.

In addition, the fan support to which the fans are attached may include predetermined fan installation locations at which a fan can be coupled, and these fan installation locations may vary from one system to the next. Also, the primary system board of a system may have fan connectors arranged at predetermined locations, which may vary from one system to the next. Thus, to allow for a fan's electrical connector to mate with a fan connector of the system board when the fan is at an allowed installation location, the fan guard may need to be designed in view of both of these constraints. In particular, the combination of the allowed installation locations of the fan support and the fan connector locations of the system board within a system determines where the connector holder of a fan guard needs to be located relative to the remainder of the fan guard in order to allow for the connector holder to be aligned with a fan connector of the system board when the fan is in an approved installation location. And because the allowed installation locations and/or fan connector locations can vary from one system to another, different fan guard designs may be needed for different systems.

As a result, a manufacturer that manufactures multiple different types of information processing systems or platforms may also need to design and manufacture (or procure) multiple different fan guards, which can increase the overall costs of the systems. For example, designing multiple different types of fan guards may require additional engineering time, which increases development costs. Moreover, the different fan guards may require different tooling to manufacture, which may increase manufacturing costs. Furthermore, the different fan guards may need to have different Stock-Keeping-Units (SKUs), which can increase logistical complexity and costs. Alternatively, the manufacturer may attempt to use the same or similar fan installation locations and fan connector locations across different systems to allow for the same fan guards to be used, but this may not always be possible, given differences in form factor, configuration, use case, etc., between systems. Moreover, limiting fan installation location and fan connector location in this manner has its own costs, such as increasing the difficulty (and hence cost) in designing the system boards.

The present disclosure addresses these and other issues by providing an adaptable fan guard system in which the connector holder is separable from the fan guards and can be removably mountable to the fan guards in a variety of configurations, which allows for greater flexibility in the installation of the fan. This installation flexibility may include the ability to change the orientation of the fans relative to a system board while still maintaining the ability to connect to the same fan connectors of the system board, e.g., by changing which fan guard the connector holder is attached to. This ability to change the orientation of the fans can allow for the fans to be installed in an information processing system regardless of which direction the system directs airflow. For example, the connector holder may be mounted to an exhaust-side fan guard for use in a front-to-rear airflow system, whereas the same connector holder could instead be mounted to the intake-side fan guard for use in a rear-to-front airflow system. Thus, the adaptable fan guard system may allow the same fan guard design to be used in multiple different systems having different airflow directions, or even to change the airflow direction of a given system post manufacture. In addition, the installation flexibility of the adaptable fan guard system may include the ability for the connector holder to be used without being mounted to any fan guard, which can allow for the connector holder to be moved about freely to engage with an electrical connector that is more remote from the fan installation location. This may allow for a decoupling (to some degree) between the installation position of the fan and the location of the electrical connector on the system board, which can provide more flexibility to system designers and allow the same fan guard design to be used with multiple differently configured systems. The ability to use a single fan guard design across multiple different computing systems can reduce development, manufacturing, and logistical costs as compared to providing different fan guards for different systems with different airflow orientations.

The adaptable fan guard system comprises two identical fan guards which are attached to either end of a fan housing of a fan. Each fan guard includes a bracket to receive a connector holder. The connector holder is configured to be removably coupled to either of the fan guards at the bracket thereof such that each fan guard can interchangeably receive the connector holder. In some examples, the connector holder is a snap fit connector that snaps into the bracket of the fan guard. Because both fan guards can removably receive the connector holder, the connector holder (and the electrical connector held thereby) is able to be moved between the intake side and the exhaust side of the fan. Thus, the fan is able to be installed in both systems with front to rear airflow and rear to front airflow. In addition, because the connector holder is removable from the fan guard and may therefore be moved, the connector holder may be moved beyond the particular location that a fixed connector holder would be located.

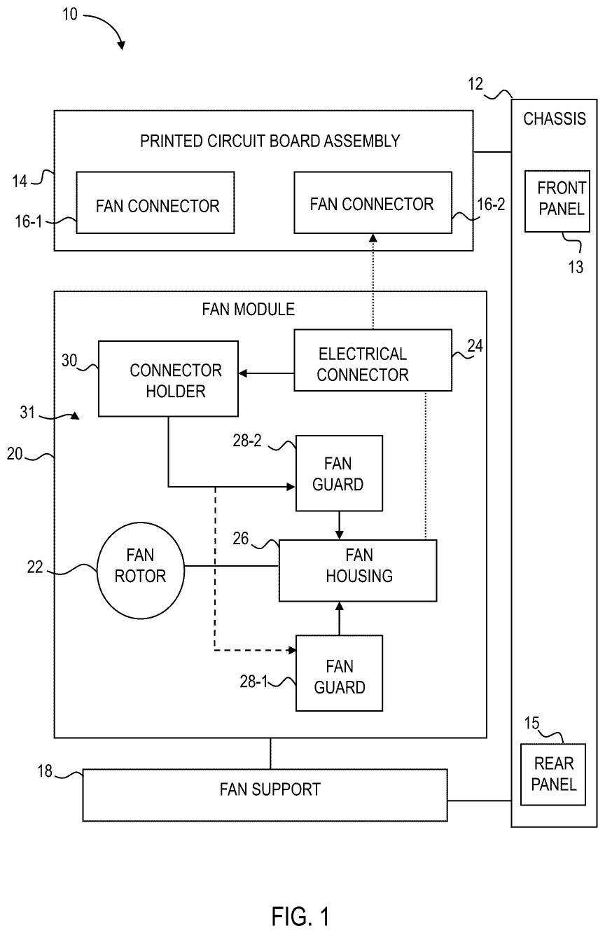

FIG. 1 is a block diagram of an example information processing system 10 including a fan module 20 having an adaptable fan guard system 31. It should be understood that FIG. 1 is not intended to illustrate specific shapes, dimensions, or other structural details accurately or to scale, and that implementations of the information processing system 10 including adaptable fan guard system 31 may have different numbers and arrangements of the illustrated components and may also include other parts that are not illustrated. In FIG. 1, physical connections (e.g. physical attachment and/or support) between components are indicated conceptually by solid lines extending between the components, whereas electrical connections between components are indicated conceptually by dotted lines extending between the components. Furthermore, connections which may be intermittent or conditional (e.g., occurring in some states but not in others) are indicated by arrows. The fan guard system 31 and the fan module 20 are illustrated in FIG. 1 in the context of the information processing system 10 to aid understanding, but some examples disclosed herein comprises the fan guard system 31 guard alone, other examples disclosed herein comprise the fan module 20 with the fan guard system 31 alone (i.e., not yet installed in any information processing system), and other examples comprise the information processing system 10 with the fan module 20 and fan guard system 31 installed therein.

System 10 includes a chassis 12 a printed circuit board assembly, or PCA, 14 housed in and/or supported by the chassis 12, one or more fan modules 20 (only one is illustrated in FIG. 1) electrically connected to the PCA 14, and a fan support 18 attached to the chassis 12 and connected to the fan modules 20. These components will be described in greater detail below.

The chassis 12 is a support structure configured to support, and in some cases house, the other components of the system. The chassis 12 may include a front panel 13 and a rear panel 15, as well as other structural members such as a base, side walls, a cover, drive cages, etc.

The PCA 14 comprises a printed circuit board (PCB) and one or more electronic components mounted to the PCB. For example, the PCA 14 may be a primary system board (e.g., a motherboard) that comprises a processor and other electronic circuitry (not illustrated), but examples are not so limited and any PCA may be used. The PCA 14 includes one or more fan connectors 16-1, 16-2 (collectively fan connectors 16) mounted to the PCB. A fan connector 16 refers to an electrical connector configured to receive (e.g., physically mate with) and electrically connect with a complimentary electrical connector of a fan (e.g., the electrical connector 24 of fan module 20, described in further detail below). The PCA 14 may supply electrical power and/or control signals to the fan modules 20 via the fan connectors 16.

As noted above, system 10 may further include a fan support 18. Fan support 18 is configured to engage with the fan modules 20 to support and secure the fan modules 20 to the chassis 12. Although shown separately in FIG. 1, in some cases the fan support 18 may be regarded as being part of the chassis 12. In some examples, the fan support 18 may extend horizontally across a width dimension of the chassis 12 (perpendicular to an airflow direction) to allow fan modules 20 to be distributed across the width of the chassis 12. In some examples, the fan support 18 comprises a cage into which the fan modules 20 are inserted. In some examples, the fan support 18 may comprise a vertically extending support member (such as a wall with airflow openings) to which the fan modules 20 are attached. In some examples, the fan support 18 may comprise a horizontal support structure which extends in front of, under, or behind the fans and to which a bottom portion of the fans are attached. In some examples, the fan support 18 may comprise portions of the base of the chassis 12, such as screw holes in the base through which screws may be inserted to attach the fans. Fan support 18 may be integrally formed with the chassis 12, i.e., formed as part of the base of chassis 12, or may be separately formed and coupled to chassis 12 by, for example, welding, adhesive, or any other suitable fastening means. In some examples, fan support 18 is directly attached to some other part, such as the PCA 14 or a tray supporting the PCA 14, which is in turn attached to chassis 12, in which case the fan support 18 may be considered as being indirectly coupled to the chassis 12. Fan support 18 may include a bracket, a rolled edge designed to receive a corresponding bracket on, e.g., a fan guard, or any other means by which a fan module such as fan module 20 may be coupled thereto. In some examples, the fan support 18 may be disposed in the chassis 12 in a region between the printed circuit board and a front panel 13 of the chassis. In other examples, support 18 may be disposed in the chassis 12 in a region between the printed circuit board and a rear panel 15 of the chassis. In other examples, the fan support 18 may be disposed on the PCA 14, at or in the front panel 13, or at or in the rear panel 15. Although FIG. 1 shows a single fan support 18, examples are not so limited and other numbers of fan supports 18 may be used. In some examples, fan support 18 is omitted and the fan modules 20 are physically attached to the chassis 12 only via the coupling which occurs due to the mating of the electrical connector 24 to fan connector 16.

Fan module 20 may include a fan housing 26 which contains one or more motors (not illustrated). The fan module 20 also includes one or more fan rotors 22 coupled to and/or contained within a fan housing 26 and operably coupled to the motor(s) such that the motor(s) drive rotation of the fan rotor(s) 22. For example, each fan rotor 22 may be coupled to a shaft of a fan motor, and the fan motor drives the shaft (and hence the rotor 22) to rotate. The fan rotors 22 each comprise blades which cause air to flow when the fan rotor 22 is rotated. In some examples, there may be multiple fan rotors 22, such as one disposed on one side of the fan housing 26 and another disposed on the other side of the fan housing 26. The fan housing 26 may have an intake side, i.e., a side which draws in air, and an exhaust side, i.e., a side which expels the air out. The fan housing 26 comprises an airflow pathway extending from the intake side to the exhaust side, with an intake opening at the intake side and an exhaust opening at the exhaust side. The fan rotor(s) 22 are disposed within this airflow pathway and drive air to flow through it. Which side of the fan housing 26 is intake side and which is the exhaust side is dependent on the configuration of the fan rotor(s) 22 and the direction in which they are driven to rotate.

Disposed on each end of the fan housing 26 may be a plurality of fan guards 28-1, 28-2 (collectively, fan guards 28). As used herein, a fan guard 28 refers to a component that couples to a fan housing 26 and extends across one of the intake or exhaust openings thereof to prevent objects (e.g., debris, fingers, etc.) from coming in contact with the internal components of the fan module 20 (particularly, the blades of the rotor 22), as well as to prevent damage to the same components. Each fan guard 28 may couple to an end of the fan housing 26; that is, a first fan guard 28-1 may be coupled to a first end of the fan housing 26 and a second fan guard 28-2 may be coupled to the opposite end of the fan housing 26, such that the body of fan housing 26 separates the fan guards 28. Each fan guard 28 may include a bracket to receive a connector holder 30; these structures are discussed further herein.

Each fan guard 28 may include attachment features that may engage with complementary features on the fan housing 26. Engagement of the attachment features on the fan guard 28 with the complementary features on the fan housing 26 may thus attach the fan guard 28 to the fan housing 26. The attachment features may be any attachment features suitable to securely attach the fan guard 28 to the fan housing 26. For example, attachment features may include snap fit connectors, interlocking features, friction-based attachment features, etc. When engaged, the attachment features of the fan guard 28 may hold the fan guard 28 to the fan housing 26 at the complementary features.

In some examples, fan guard 28-1 and fan guard 28-2 may be identical to one another. This may allow fan guard 28-1 and fan guard 28-2 to be installed interchangeably on the fan housing 26. Said differently, when fan guards 28 are identical, neither fan guard 28 necessarily must be coupled to a particular end of the fan housing 26. As such, features included as part of the fan guards 28, such as the brackets to receive connector holders 30, may also be identical on each fan guard 28. This may allow for ease of installation because a particular fan guard 28 does not have to be located for installation on a particular end of the fan housing 26; rather, any available fan guard 28 may be used. This also allows for reduced development, manufacturing, and logistical costs, as only a single fan guard design with a single SKU/part number needs to be produced.

Moreover, as described previously, a connector holder 30 may be removably coupled to a fan guard 28 at a bracket of the fan guard. The connector holder 30 is physically distinct from the fan guards 28 and removable therefrom, as opposed to other approaches in which a connector holder is integrally formed with, or otherwise permanently attached to, the body of one of the fan guards. Furthermore, because both fan guards 28 have brackets to receive the connector holder 30, connector holder 30 may be coupled to either fan guard 28, at either bracket thereof, with the selection made based on factors such as the desired direction of airflow through the system and the location of the fan connectors 16 on the PCA 14. The connector holder 30 may attach to the brackets of the fan guards 28 via an attachment feature on the connector holder 30 engaging with complementary features on the bracket. For example, connector holder 30 may include a latching feature that engages with the bracket to hold the connector holder 30 in place with respect to the bracket. However, examples are not so limited, and other varieties of attachment features may be used. For example, connector holder 30 may couple to a fan guard 28 at fasteners, by interlocking features, by a friction-based attachment, or by any other suitable attachment feature.

The physical dissociation of the connector holder 30 from the fan guards 28 is one thing which enabled the two fan guards 28-1 and 28-2 to be identical to one another, which has advantages as discussed above. In contrast, in other approaches one of the fan guards has an integral connector holder while the other fan guard has none, necessitating two different fan guard designs with different SKUs/part numbers. The ability to connect the connector holder 30 to either fan guard 28 can also allow the same type of fan guards to be used in multiple different system configurations. For instance, the same type of fan guard 28 may be usable in two different systems having different airflow directions, with the connector holder 30 being attached to the exhaust-side fan guard 28 in one system and with the connector holder 30 being attached to the intake-side fan guard 28 in the other. The ability to remove the connector holder 30 from a fan guard to which it is attached and the ability to attach it to either of the fan guards 28 can also facilitate retrofitting, upgrading, or otherwise changing the configuration of a given system post-manufacture, such as, for example, reconfiguring a system which was initially a front-to-rear airflow system to be a rear-to-front airflow system by reversing the orientation of the fans and changing which side the connector holder 30 is attached to. Furthermore, because the connector holder 30 is separable from the fan guards, in some systems it does not have to be connected to any fan guard and can instead be replaced to a remote location in the system, which can give the system designer greater flexibility in where fan connectors are located on the system board and/or where fans are disposed in the system.

An electrical connector 24 may be included within the fan module 20 and may removably couple to a fan connector 16 on the PCA 14. Although FIG. 1 shows electrical connector 24 as couplable with fan connector 16-2, examples are not so limited and electrical connector 24 may be coupled to any available fan connector 16 on the PCA 14. Electrical connector 24 may couple to the fan module 20 at the connector holder 30. More particularly, the connector holder 30 may include engagement features to engage with the electrical connector 24, thus holding electrical connector 24 in a position to mate with a fan connector 16. The engagement features may be slots on the connector holder 30 designed to receive corresponding tabs on the electrical connector 24, fasteners such as screws that couple the electrical connector 24 to the connector holder 30, or any other suitable engagement feature to allow electrical connector 24 to be received at connector holder 30.

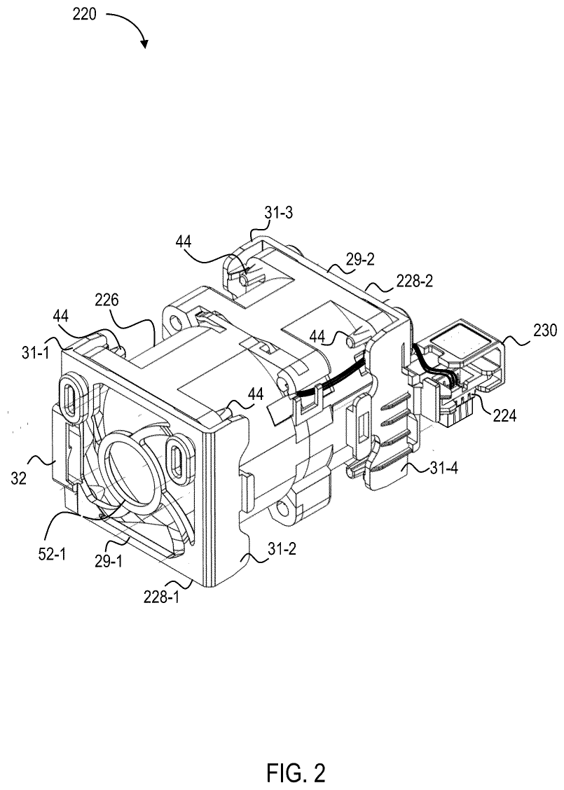

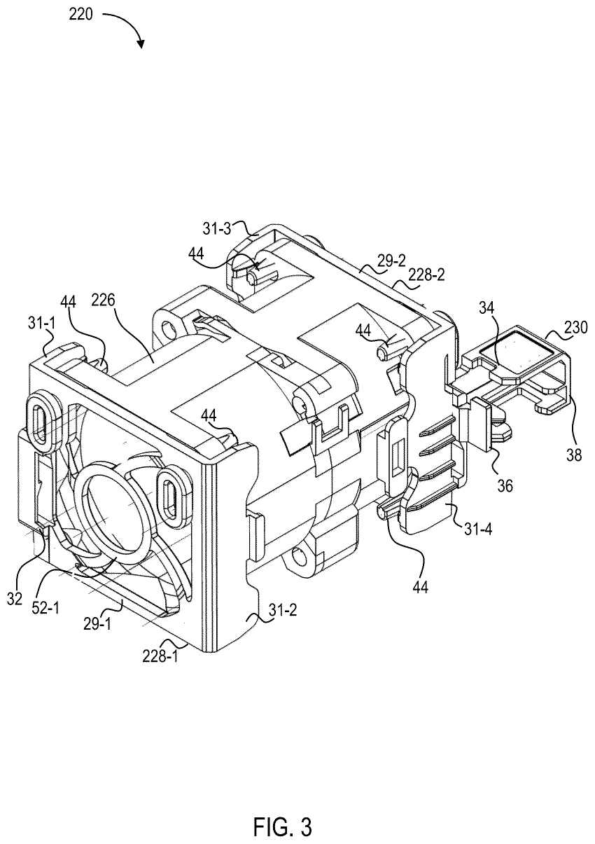

FIGS. 2-6 show an example of a fan module 220 that could be used in an information processing system such as system 10. Fan module 220 may be one implementation example of fan module 20 shown in and described with respect to FIG. 1 and may be used in a system such as system 10, described with respect to FIG. 1. Fan module 220 thus comprises components which correspond to (i.e., are implementation examples of) components of the fan module 20, and the correspondence between such components is indicated herein by the components having reference numbers with the same last two digits, such as 26 and 226. Aspects of the fan module 20 and its components described above may also be applicable to the fan module 220 and its corresponding components, but the fan module 20 and its components are not limited to the fan module 220 and its components, which are just one example of how the fan module 20 may be implemented. In some instances, aspects of the fan module 20 already described above, which are also applicable to the fan module 220, are not described below to avoid duplicative description.

Fan module 220 includes a fan housing 226 and a plurality of fan guards 228-1, 228-2 (collectively fan guards 228) coupled thereto, with a first fan guard 228-1 being coupled to a first end of the fan housing 226 and a second fan guard 228-2 being coupled to a second end of the fan housing 226. The second end of the fan housing 226 is located opposite the first end of the fan housing, such that first fan guard 228-1 is located opposite the second fan guard 228-2. Each fan guard 228 includes a front face and a pair of wings extending perpendicularly from the front face. More particularly, first fan guard 228-1 includes front face 29-1 and wings 31-1 and 31-2 extending from front face 29-1, and second fan guard 228-2 includes front face 29-1 and wings 31-3 and 314 extending from front face 29-2. In some examples, wings 31 may aid in aligning the fan guards 228 with the fan housing 226 when installing the fan guards 228. Fan guards 228 further include a central opening 52 in the fan face 29, with opening 52-1 being formed in fan face 29-1 and opening 52-2 formed in fan face 29-2. When the fan module 220 is coupled to a fan connector, as described with respect to FIG. 1, openings 52 may allow air to flow through the fan guard 228.

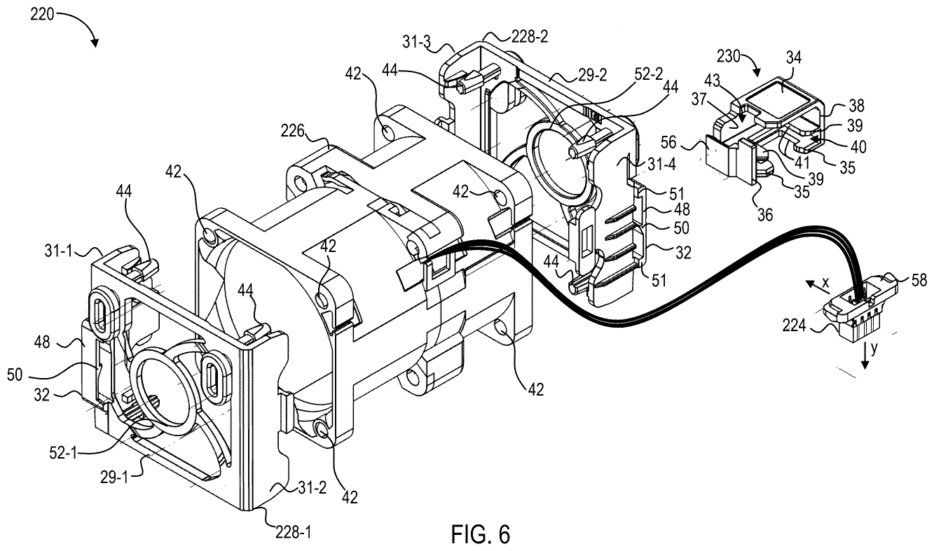

In some examples, fan guards 228 are removably coupled to the fan housing 226 by releasable connectors, such as snap fit connectors. For example, as shown in FIGS. 2-6, a plurality of protrusions 44 may extend rearwardly from fan guards 228. These protrusions 44 may include barbs, as shown in FIGS. 2-6, but may also have varying thickness or include another feature that aids in engagement with complementary features on the fan housing 226. More particularly, as shown in FIG. 6, fan housing 226 may include a plurality of openings 42 to receive correspondingly located protrusions 44. When a fan guard, such as fan guard 228-1, is installed onto fan housing 226, wings 31-1 and 31-2 may be used to aid in aligning fan guard 228-1 with fan housing 226. Fan guard 228-1 is then moved onto fan housing 226 such that protrusions 44 align with openings 42 and can be inserted therein. In examples where protrusions 44 have integrally formed barbs, the barbs may deform slightly as protrusions 44 are moved through openings 42 and, upon moving through the openings 42, may return to their original shape and position, thus preventing protrusions 44 from being easily removed from openings 42. In this manner, first fan guard 228-1 may be securely attached to the fan housing 226. Second fan guard 228-2 may be installed in a similar manner.

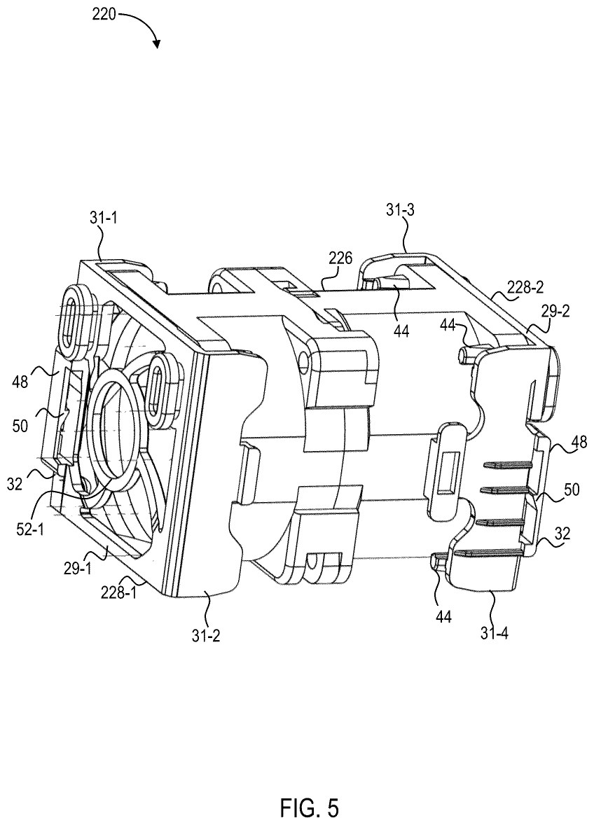

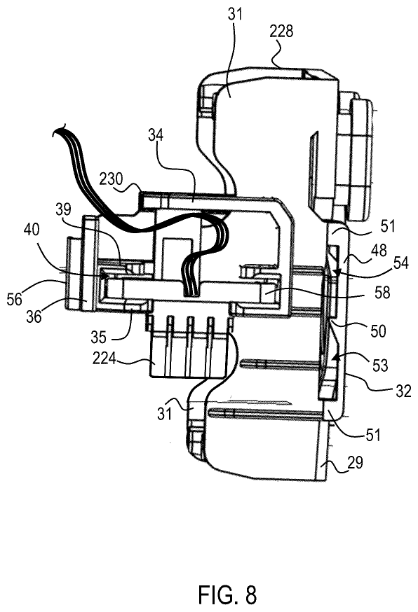

Fan guards 228 further includes brackets 32. As shown in FIGS. 2-6, brackets 32 extend outwardly from the fan guards 228. More particularly, each bracket 32 comprises a vertical support 48 which is spaced apart from and extends parallel to the front face 29 of the fan guard 228, as well as attachment portions 51 which extend between the front face 29 and the vertical support 48. As shown particularly in FIGS. 5 and 6, attachment portions 51 extend away from the front face 29 to allow the vertical support 48 to be spaced apart from the front face 29. A protrusion 50 extends from the vertical support 48. More particularly, protrusion 50 extends perpendicularly from the support 48 on an inner surface thereof such that protrusion 50 extends back toward the front face 29. Protrusion 50 selectively engages with a connector holder 230, described further herein. The space between the support 48 and the front face 29 may include a bottom region 53 below the protrusion 50 and a top region 54 above the protrusion, as shown in FIG. 8 (the purpose of these regions 53 and 54 will be described in more detail below).

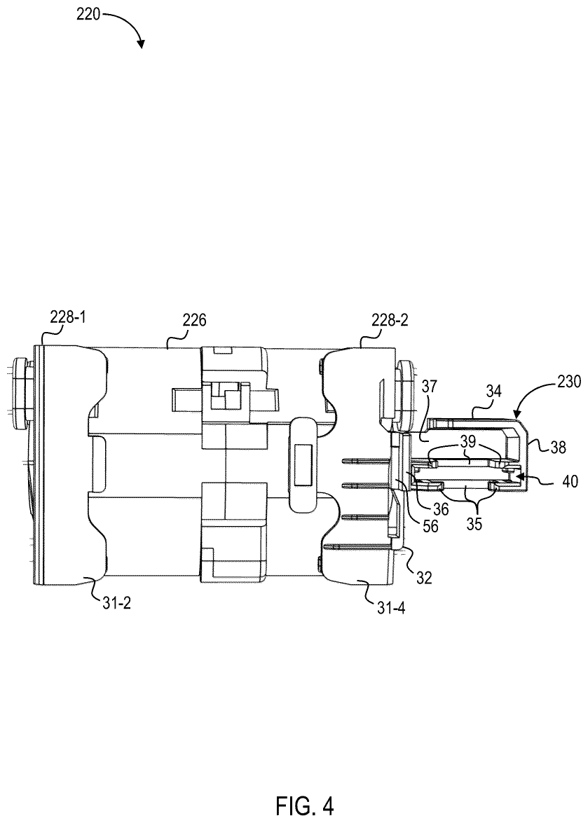

Connector holder 230 may removably couple interchangeably to bracket 32 of either one of the fan guards 228. As shown particularly in FIGS. 4 and 6, connector holder 230 includes a front vertical wall 36, a rear vertical wall 38, and a side vertical wall 37 extending between and connecting the front wall 36 with the rear wall 38. In addition, connector holder 230 comprises a top horizontal wall 34 extending from a top portion of the rear wall 38 towards the front wall 36, a bottom horizontal wall 35 extending from a bottom portion of rear wall 38 to the front wall 36, and intermediate horizontal wall 39 between the top and bottom walls 34, 35 and extending from the rear wall 38 to the front wall 36. As shown in FIG. 6, the bottom wall 35 and the intermediate wall 39 each comprise a notch 41 in a middle region thereof. These notches 41 may allow for the connector 224 and its cable to be inserted into connector holder 230, as described in more detail below. Furthermore, there is a gap or opening 43 between the top wall 34 and the front wall 36, through which cables of the connector 224 may be routed. In addition, a slot 40 is formed between the bottom wall 35 and the intermediate wall 39, such slot 40 being sized to receive a portion of an electrical connector 224 as described further herein.

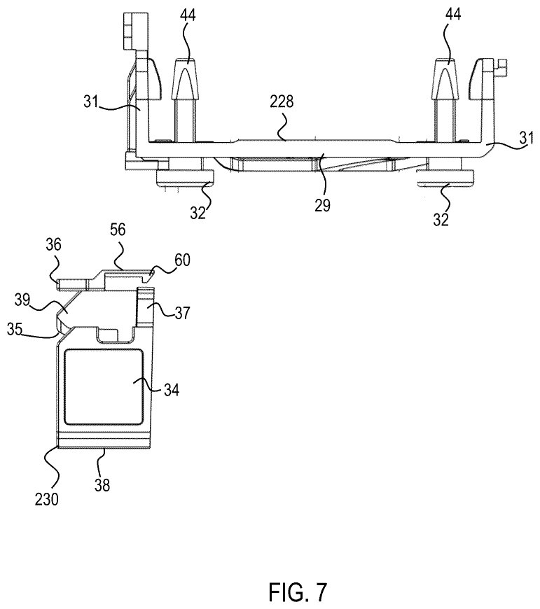

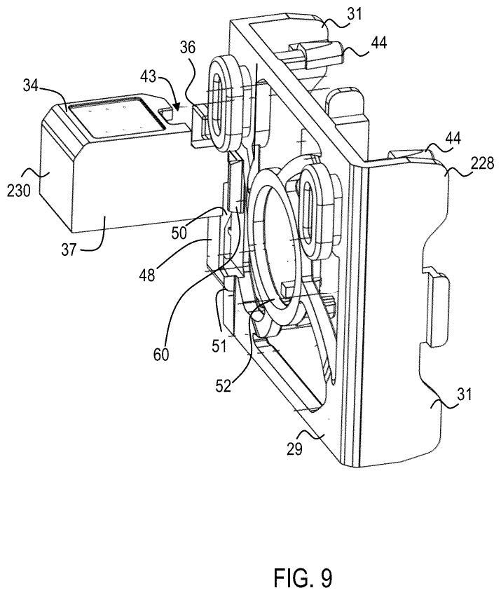

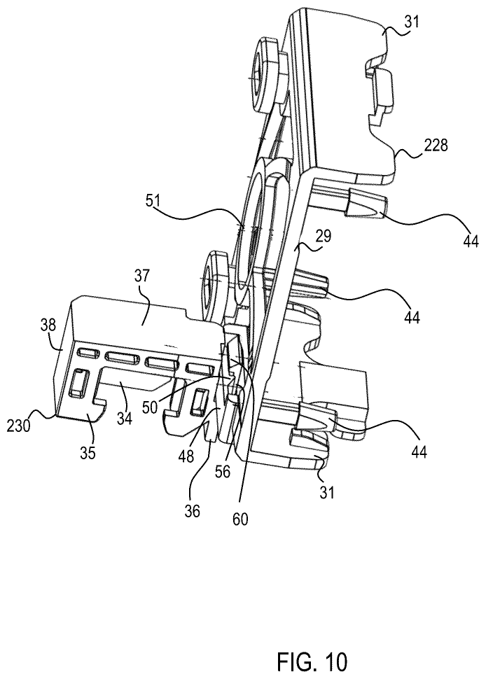

In addition, connector holder 230 may include a latching feature 56 extending from the front wall 36 and parallel thereto. As shown in FIGS. 7 and 10, the latching feature 56 may comprise an integrally formed lip 60. Lip 60 may engage with a bracket 32. More particularly, as shown in FIGS. 8-10, the connector holder 230 may engage with bracket 32 by inserting the latching feature 56 into the space between the vertical support 48 and the front face 29 until the lip 60 passes beyond the vertical support 48 and latches thereto. In some examples, the latching feature 56 may initially be inserted into the region 53 below the protrusion 50, as there may be more clearance between the vertical support 48 and the front face 29 in this region 53 (as compared to the region 54 above the protrusion 50) and therefore the lip 60 can pass between the vertical support 48 and the front face 29 in this region. 53 Once the connector holder 230 is engaged with bracket 32 in this manner, connector holder 230 may be moved linearly upward along the bracket 32. Such linear movement may occur until latching feature 56 passes vertically over protrusion 50. As the latching feature 56 passes the protrusion 50, it may slide along the sloped surface of the protrusion 50 and either or both of the latching feature 56 and the vertical support 48 deflect to allowing the latching feature 56 to pass the protrusion 50. When the latching feature 56 has fully moved past the protrusion 50 into the region 54 above the protrusion 50, the latching feature 56 and/or vertical support 48 snap back into their resting positions and thereafter the protrusion 50 blocks the latching feature 56 from moving back downward, thereby removably locking the connector holder 230 into place with respect to the bracket 32, as shown in FIG. 9. As shown in FIG. 10, protrusion 50 “holds” (vertically supports and prevents downward movement of) connector holder 230 by the engagement of the protrusion 50 with the bottom side of the latching feature 56. In addition, in this state the hooked portion of the lip 60 engages with the edge of the vertical support 48 such that the vertical support 48 blocks the lip 60 from moving laterally relative to the vertical support 48, thereby preventing withdrawal of the latching feature 56 from the space between the vertical support 48 and the front face 29. In this manner, the protrusion 50, vertical support 48, lip 60, and latching feature 56 interact to attach the connector holder 230 to the bracket 32. The connector holder 230 can be removed from the bracket 32 by a user manually deflecting the protrusion outward, thus allowing the latching feature 56 to move downward into the space below the protrusion 50, and then lifting the lip 60 to disengage it from the vertical support 48 and removing the latching feature 56 from the bracket 32.

Importantly, because each of fan guards 228 have at least one bracket 32 which is able to receive the connector holder 230, the connector holder 230 may be coupled to either the first fan guard 228-1 or the second fan guard 228-2. As such, the fan 220 may be positioned within a system, such as system 10, such that the fan module 220 is able to provide both rear-to-front airflow (by orienting the intake side of the fan towards a rear panel of the chassis) and front-to-rear airflow (by orienting the exhaust side of the fan towards the rear panel of the chassis) over the other components of the system.

An electrical connector 224 may be removably coupled with connector holder 230. As shown in FIGS. 2 and 8, the electrical connector 224 may be received within the slot 40 of connector holder 230. More particularly, as shown in FIG. 6, electrical connector 224 may include a flange 58. Flange 58 may be inserted into the slot 40 of the connector holder 230 and, by translating the electrical connector 224 and flange 58 in a direction (x) transverse to a mating axis (y) of the electrical connector 224, the electrical connector 224 may be received within the connector holder 230. FIG. 8 illustrates the connector 224 inserted into the connector holder 230. As shown in FIG. 6, electrical connector 224 may be connected to the fan module 220 by a wire, such that electrical connector 224 provides power to the fan module 220, and particularly to the fan rotor contained therein, when the electrical connector 224 is coupled with a fan connector, such as fan connectors 16, discussed with respect to FIG. 1. More particularly, the electrical connector 224 is electrically coupled with a fan connector by engaging with the fan connector in a direction that is perpendicular to the mating axis of the electrical connector 224, such that the electrical components of electrical connector 224, shown in FIG. 8, are able to mate with corresponding components on the fan connector.

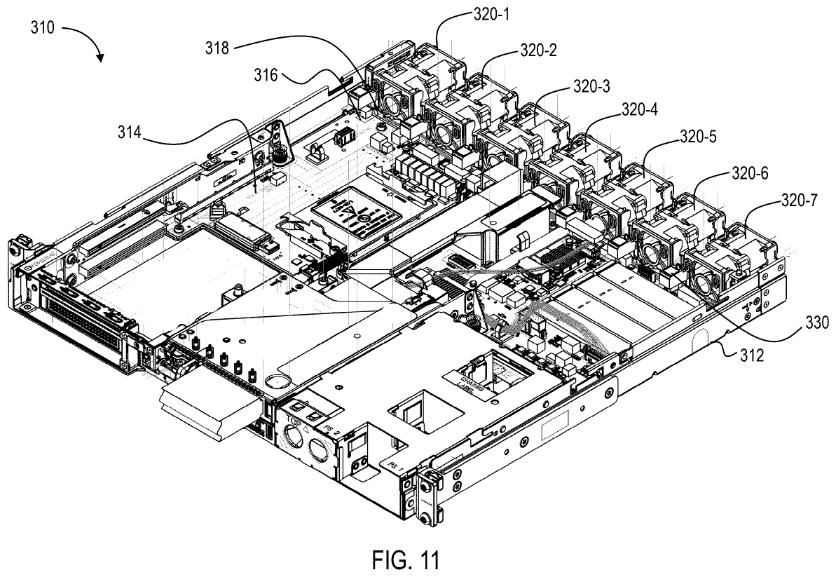

FIG. 11 shows an example system 310 having a plurality of fan modules 320 having adaptable fan guards. System 310 may be one implementation of a system such as system 10, shown in and described with respect to FIG. 1, and may include one implementation of fan modules 320 such as fan modules 20, shown in and described with respect to FIG. 1. As shown in FIG. 11, system 310 includes a chassis 312 supporting a PCA 314. A fan connector 316 is disposed on the PCA 314; although only one fan connector 316 is shown in system 310, examples are not so limited and more fan connectors 316 may be included.

A plurality of fan modules 320-1, 320-2, 320-3, 320-4, 320-5, 320-6, 320-7 (fan modules 320) may be coupled to the chassis 312. More particularly, fan modules 320 may be coupled to the chassis 312 at a fan support 318, allowing the fan modules 320 to be supported by the chassis 312.

As discussed previously with respect to FIGS. 2-10, each fan module 320 may include a plurality of fan guards to which a connector holder 330 may be coupled. Although only a single connector holder 330 is shown in FIG. 11, it is to be understood that each fan module 320 has a corresponding connector holder 330. An electrical connector, such as electrical connector 24 described with respect to FIG. 1 or electrical connector 224 described with respect to FIGS. 2-10, may be received within electrical connector 330. The electrical connector may then be coupled to fan connector 316, allowing power to flow from the PCA 314 to the fan module 320, and more particularly to the rotor contained therein.

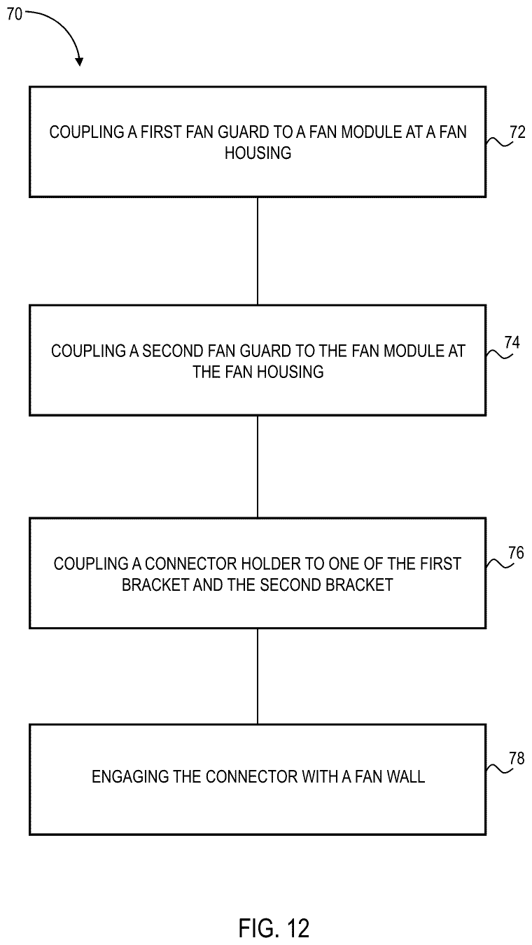

FIG. 12 is an example method 70 for installing fans with an adaptable fan guard consistent with the present disclosure. At 72, method 70 includes coupling a first fan guard to a fan module at a fan housing. As described with respect to FIGS. 2-10, the first fan guard may be couped to the fan housing via a snap fit connector, although examples are not so limited. The first fan guard may further include a first bracket, which may extend outwardly from the first fan guard.

At 74, method 70 includes coupling a second fan guard to the fan module at the fan housing. The second fan guard may be coupled to the fan module at an opposite end of the housing to the first fan guard, such that the first fan guard and the second fan guard are separated by the length of the fan housing. As with the first fan guard, the second fan guard may be coupled to the fan housing by a snap fit connector or by another suitable connector and may include a second bracket extending outwardly from the second fan guard.

At 76, method 70 includes coupling a connector holder to one of the first bracket and the second bracket. The selection of the first bracket or the second bracket for the connector holder is made based on the direction of airflow of the information processing system into which the fan module is to be installed. If the system airflow is rear-to-front, the connector holder will be installed such that the fan can be installed with the intake side of the fan housing also facing the rear to provide rear-to-front cooling. By contrast, if the system airflow is front-to-rear, the connector holder will be installed such that the fan can be installed with the exhaust side of the fan housing facing the rear to provide front-to-rear cooling.

More particularly, coupling a connector holder at 76 comprises engaging a snap fit connection between the connector holder and the bracket of the fan guard. As described with respect to FIGS. 2-10, the connector holder includes a latching feature having an integrally formed lip. When the connector holder is initially engaged with the bracket, the connector holder is able to be moved linearly with respect to the bracket. The connector holder is moved linearly with respect to the bracket until the connector holder's lip passes over a protrusion of the bracket, removably locking the connector holder into place with respect to the bracket.

A fan plug may further be coupled to the connector holder. More particularly, as described with respect to FIGS. 2-10, the fan plug may be coupled with the connector holder by sliding a flange of the fan plug into a corresponding slot on the connector holder. Once coupled to the connector holder, the fan plug may be linearly extended and coupled with a fan connector located on a fan wall or PCA of the information processing system.

At 78, method 70 may include engaging the connector with a fan wall 78. The fan wall may be installed within the information processing system and engaging the connector with the fan wall may comprise installing the full fan module, including the fan plug, into the information processing system such that the fan module is able to provide cooling to the system.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An information processing system, comprising:
a printed circuit board assembly comprising a plurality of fan connectors;
a chassis supporting the printed circuit board assembly;
a fan support coupled with the chassis; and
a fan module attached to the fan support, wherein the fan module comprises:
a fan rotor;
an electrical connector configured to be electrically coupled with a fan connector of the plurality of fan connectors;
a fan housing containing the fan rotor;
a pair of fan guards coupled to the fan housing, wherein each fan guard includes a bracket; and
a connector holder holding the electrical connector, the connector holder interchangeably and removably couplable to the bracket of each one of the pair of fan guards.

2. The system of claim 1, further comprising a mounting feature to removably couple the fan module to the fan support.

3. The system of claim 2, wherein the mounting feature couples to an edge portion of the fan support.

4. The system of claim 1, wherein the connector holder engages with the bracket via a snap fit.

5. The system of claim 1, wherein:
the pair of fan guards comprises a first fan guard and a second fan guard;
the fan module is orientable in a first orientation and a second orientation;
in the first orientation, the connector holder engages the bracket of the first fan guard; and
in the second orientation, the connector holder engages the bracket of the second fan guard.

6. The system of claim 5 wherein:
the chassis comprises a front panel and a rear panel;
the first fan guard is coupled to an intake side of the fan housing;
the second fan guard is coupled to an exhaust side of the fan housing;
in the first orientation, the intake side of the fan housing faces the rear panel to provide rear-to-front airflow; and
in the second orientation, the exhaust side of the fan housing faces the rear panel to provide front-to-rear airflow.

7. A fan mounting system, comprising:
a first fan guard configured to couple to a first end of a fan housing containing a fan module, wherein the first fan guard includes a first bracket;
a second fan guard configured to couple to a second end of the fan housing, wherein:
the second fan guard includes a second bracket; and
the second end of the fan housing is located opposite the first end of the fan housing; and
a connector holder configured to removably couple interchangeably with the first bracket and the second bracket.

8. The fan mounting system of claim 7, wherein the first bracket and the second bracket further comprise:
a support extending parallel from the first fan guard and the second fan guard; and
a protrusion extending perpendicular from the support.

9. The fan mounting system of claim 7, wherein the connector holder further comprises:
a front wall, a rear wall, and a pair of side walls extending between and connecting between the front wall and the rear wall; and
a latching feature extending from and parallel to the front wall, wherein the latching feature further comprises an integrally formed lip extending from the latching feature, wherein the latching feature engages with the first bracket and the second bracket.

10. The fan mounting system of claim 9, wherein engagement of the latching feature with the first bracket and the second bracket removably locks the connector holder in a final position.

11. The fan mounting system of claim 7, wherein the connector holder engages with the first bracket and the second bracket using a snap fit.

12. The fan mounting system of claim 7, wherein the fan module further comprises:
a fan rotor oriented to provide air flow; and
an electrical connector configured to be electrically coupled with a fan connector to provide power to the fan rotor.

13. The fan mounting system of claim 12, wherein:
the connector holder includes a slot;
the electrical connector includes a flange; and
the electrical connector is configured to be removably coupled to the connector holder by insertion of the flange of the electrical connector into the slot of the connector holder by translation transverse to a mating axis of the electrical connector.

14. The fan mounting system of claim 13, wherein the electrical connector is further configured to be electrically coupled with a fan connector by engaging with the fan connector in a direction perpendicular to the mating axis of the electrical connector.

15. A method of installing fans in an information processing device, comprising:
coupling a first fan guard to a fan module at a fan housing, wherein the first fan guard includes a first bracket
coupling a second fan guard to the fan module at the fan housing, wherein the second fan guard includes a second bracket;
coupling a connector holder to one of the first bracket and the second bracket, wherein selection of the first bracket or the second bracket is based on an airflow direction of the information processing system; and
engaging the connector with a fan wall installed within the information processing system.

16. The method of claim 15, further comprising:
coupling a fan plug to the connector holder;
extending the fan plug linearly; and
coupling the fan plug with a fan connector located on the fan wall.

17. The method of claim 16, wherein coupling a fan plug to the connector holder further comprises inserting a flange of the fan plug into a slot of the connector holder.

18. The method of claim 15, wherein coupling the connector holder to one of the first and second bracket further comprises:
engaging a snap fit connection between the connector holder and the bracket; and
moving the connector holder linearly with respect to the bracket.

19. The method of claim 18, wherein moving the connector holder linearly with respect to the bracket comprises removably locking the connector holder into a final position.

20. The method of claim 19, wherein removably locking the connector holder into a final position comprises moving an integrally formed lip of the connector holder over a protrusion extending from the bracket.
